(19) United States
(12) Patent Application Publication
(10) Pub. No.: US 2026/0107439 A1
(43) Pub. Date: Apr. 16, 2026

(54) Semiconductor device and manufacturing method thereof

(71) Applicant: Fujian Jinhua Integrated Circuit Co., Ltd., Quanzhou City (CN)

(72) Inventors: Peiyu Xu, Quanzhou City (CN); JIANSHAN WU, Quanzhou City (CN); Lizhen Jiang, Quanzhou City (CN)

(21) Appl. No.: 18/954,458

(22) Filed: Nov. 20, 2024

(30) Foreign Application Priority Data
Oct. 12, 2024 (CN) 202411425691.X

(51) Int. Cl. H10B 12/00

(52) U.S. Cl. CPC H10B 12/315; H10B 12/033

(57) ABSTRACT

The invention discloses a semiconductor device. The semiconductor device includes a substrate, a plurality of first lower electrodes are positioned on the substrate, the first lower electrodes are arranged in an array along a first direction, a second direction and a third direction, the first direction, the second direction and the third direction are not perpendicular to each other. The outer contour of each first lower electrode is circular, a plurality of second lower electrodes are positioned on the substrate, and the outer contour of each second lower electrode includes a main body and three protruding parts, wherein the main body is circular, and the three protruding parts are arc-shaped, and extend outward from the center of the main body along a fourth direction, a fifth direction and a sixth direction respectively.

### BACKGROUND OF THE INVENTION

### 1. Field of the Invention

The invention relates to a semiconductor device and a manufacturing method thereof, in particular to a semiconductor memory device and a manufacturing method thereof.

### 2. Description of the Prior Art

With the trend of miniaturization of various electronic products, the design of semiconductor devices must also meet the requirements of high integration and high density. For dynamic random access memory (DRAM) with recessed gate structure, because it can obtain longer carrier channel length in the same semiconductor substrate to reduce the leakage of capacitor structure, it has gradually replaced DRAM with only planar gate structure under the current mainstream development trend. Generally speaking, dynamic random access memory with concave gate structure is an array area formed by a large number of memory cells, which are used to store information, and each memory cell can be composed of transistor components and capacitor components in series to receive voltage information from word line (WL) and bit line (BL). In response to product requirements, the density of memory cells in the array area must be continuously increased, resulting in increasing difficulty and complexity in related manufacturing processes and designs. Therefore, the existing technology or structure needs to be further improved to effectively improve the efficiency and reliability of related memory devices.

### SUMMARY OF THE INVENTION

The invention provides a semiconductor device, which is characterized by comprising a substrate, a plurality of first lower electrodes are positioned on the substrate, the first lower electrodes are arranged in an array along a first direction, a second direction and a third direction, wherein the first direction, the second direction and the third direction are not perpendicular to each other, and the outer contour of each first lower electrode is circular, and a plurality of second lower electrodes positioned on the substrate, and the outer contour of each second lower electrode includes a main body and three protruding parts, wherein the main body is circular, and the three protruding parts are arc-shaped and extend outward from the center of the main body along a fourth direction, a fifth direction and a sixth direction respectively.

The invention also provides a semiconductor device, which is characterized by comprising a substrate, a plurality of first lower electrodes and second lower electrodes located on the substrate, and the first lower electrodes are arranged adjacent to each other in an array, wherein, when viewed from a cross section, each first lower electrode presents an I-shaped profile and each second lower electrode presents a U-shaped profile.

The present invention is characterized in that, when viewed from the top, the second capacitor through hole OP2 is located in the second area A2, and the second lower electrode BE2 in the second capacitor through hole OP2 surrounds the periphery of the first lower electrodes BE1 of the plurality of first capacitor through holes OP1, and the shape of the second lower electrode BE2 is different from that of the first lower electrode BE1. In the manufacturing process, the second area A2 is adjacent to the blank area (that is, the third area A3) where elements are not formed, so there is a big difference in element density between the two areas, which is easily affected by the loading effect and leads to the damage of the capacitor structure in the second area A2. In the second area A2, the second capacitor through hole OP2 with a larger area and a special shape is manufactured by overlapping the first groove R1 and the second groove R2, so that the second capacitor through hole OP2 has a larger coverage area compared with a plurality of first capacitor through holes OP1 located in the first area A1, and the second capacitor through hole OP2 is composed of three first capacitor through holes OP1 and a central through hole, and has a stable structure and is less likely to be damaged due to loading effect. Therefore, the invention is helpful to improve the quality of the capacitor structure located in the edge region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings provide a further understanding of embodiments of the present invention and are incorporated in and constitute a part of this specification. These drawings and descriptions are used to explain the principles of some embodiments. It should be noted that all diagrams are schematic diagrams, and the relative dimensions and proportions have been adjusted for the convenience of explanation and drawing. The same symbols represent corresponding or similar features in different embodiments.

FIGS. 1 to 7 illustrate the steps of the manufacturing method of a semiconductor device in the first embodiment of the present invention, wherein the upper half of FIGS. 1 to 7 is a top view of the semiconductor device, and the lower half is a corresponding cross-sectional view of the semiconductor device.

FIG. 8 shows a partially enlarged top view of the first supporting opening SOP1, the second supporting opening SOP2, the first lower electrode BE1 and the second lower electrode BE2 of the semiconductor device of the present invention.

FIG. 9 and FIG. 10 are schematic cross-sectional views of semiconductor devices according to two other different embodiments of the present invention respectively.

In which, the reference numerals are explained as follows:
100: Substrate
110: Supporting stacked layers
111: First supporting layer
112: Second supporting layer
113: Third supporting layer
114: Fourth support layer
115: Fifth supporting layer
122: Polysilicon layer
124: Oxide layer
126: Bottom anti-reflective coating layer
128: Photoresist layer
130: Capacitor dielectric layer
140: Protruding part
142: Main body
200: Range
210: Recess (Void)
211: Fully filled structure
212: Partially filled structure
A1: First area
A2: Second area
A3: Third area
AE1, AE2, AE3, AE4, AE5, AE6, AE7, AE8, AE9, AE10, AE11, AE12: Arc boundary
BE1: First lower electrode
BE2: Second lower electrode
C1: First capacitor structure
C2: Second capacitor structure
D1: First direction
D2: Second direction
D3: Third direction
D4: Fourth direction
D5: Fifth direction
D6: Sixth direction
O: Central point
OP1: First capacitor though hole
OP2: Second capacitor though hole
P: First pitch
R1: First groove
R2: Second groove
R3: Third groove
SOP1: First supporting opening
SOP2: Second supporting opening
SNP: Contact pad (storage node pad)
SNISO: Insulated sidewall
TE: Upper electrode layer
W1: First size
W2: Second size
W3: Third dimension
W4: Fourth size

### DETAILED DESCRIPTION

Although specific configurations and arrangements are discussed in this specification, it should be understood that this is only done for illustrative purposes. Those skilled in the art will recognize that other configurations and arrangements can be used without departing from the spirit and scope of this disclosure. It is obvious to those skilled in the relevant art that the disclosure of this case can also be used in various other applications.

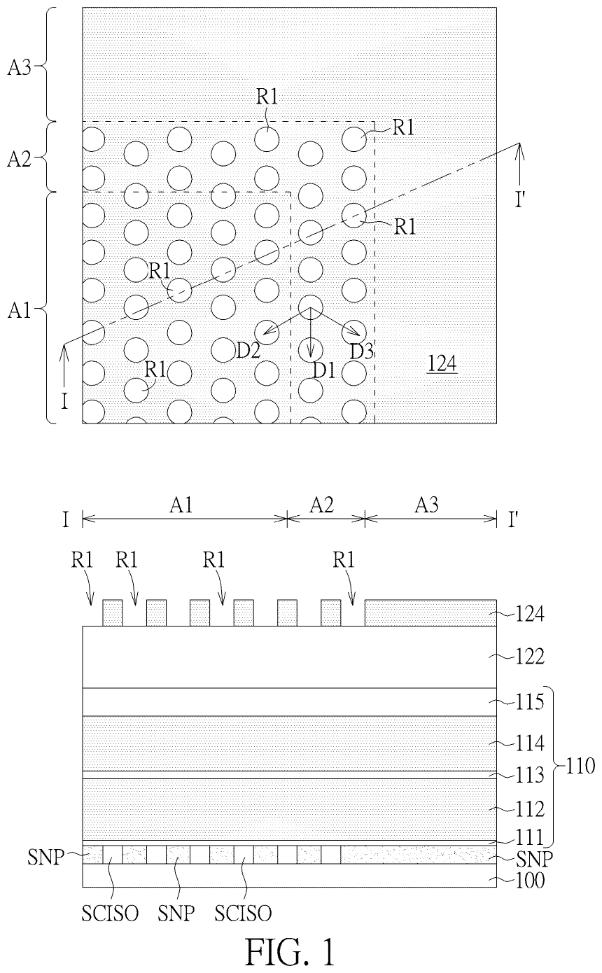

Please refer to FIG. 1 to FIG. 7, which are schematic steps of the manufacturing method of a semiconductor device in the first embodiment of the present invention. In which the upper half of FIGS. 1 to 7 is a top view of the semiconductor device, and the lower half is a corresponding cross-sectional view of the semiconductor device. First, the upper half of FIG. 1 is a top view of a semiconductor device, and the lower half of FIG. 1 is a sectional view taken along section line I-I′. As shown in FIG. 1, a substrate 100 is provided, such as a silicon substrate, a silicon-containing substrate (such as SiC, SiGe, etc.) or a silicon-on-insulator (SOI) substrate, or other suitable material layers. At least one shallow trench isolation (STI, not shown) is formed in the substrate 100, and multiple active area (AA, not shown) are defined in the substrate 100. In addition, a plurality of gates, such as buried gates, can be formed in the substrate 100, wherein the buried gates can be used as buried word line (BWL, not shown) of semiconductor devices. As these structures for forming active regions, shallow trench isolation, buried gates, etc. belong to the well-known technology in the field, they are not repeated here. In FIG. 1, the substrate 100 represents the structural layer containing the above elements.

In addition, a plurality of bit line (BL) and a plurality of storage node pads (SNPs) are formed on the substrate 100. Although the bit lines are not specifically depicted in the drawings of this embodiment, however, those skilled in the art can easily understand that each bit line extends parallel to each other, is electrically isolated from the buried gate located in the substrate 100 by an insulating layer (not shown, for example, including a silicon oxide-silicon nitride-silicon oxide structure) covering the top surface of the substrate 100, and is electrically connected to the substrate 100 by a bit line contact (BLC) formed correspondingly below each bit line.

Among them, adjacent storage node pads SNP are isolated from each other by a storage node contact isolation SCISO arranged directly above each buried gate. In this way, the storage node pad SNP can be electrically connected to the substrate 100 to receive and transmit voltage signals from the substrate 100 (such as transistor components in the substrate 100). In an embodiment, the SNP of the storage node pad includes, for example, metal materials with low resistance such as aluminum (Al), titanium (Ti), copper (Cu) or tungsten (W), but is not limited thereto.

As shown in FIG. 1, the supporting stacked layer 110 is formed on the substrate 100. In detail, the supporting stacking layer 110 includes, for example, a plurality of material layers alternately stacked. In this embodiment, the supporting stacked layer 110 includes, for example, a first supporting layer 111 (including silicon nitride or silicon carbonitride, for example), a second supporting layer 112 (including borophosphosilicate glass (BPSG), for example), a third supporting layer 113 (including silicon nitride or silicon carbonitride, for example), a fourth supporting layer 114 (including silicon oxide, for example), and a fifth supporting layer 115 (including silicon nitride, for example). Preferably, the second supporting layer 112 and the fourth supporting layer 114 may have a relatively large thickness, for example, about 5 times to more than 10 times the thickness of the nitride layer (including the first supporting layer 111, the third supporting layer 113 or the fifth supporting layer 115, for example). In this way, the overall thickness of the supporting layer structure 110 is about 1600 angstroms to about 2000 angstroms, but it is not limited to this. It should be understood by those skilled in the art that the specific stacking number of the oxide layer and the nitride layer is not limited to that shown in FIG. 1, but can be adjusted to other layers according to actual needs.

As shown in FIG. 1, a polysilicon layer 122 as a mask layer and an oxide layer 124 are also formed on the supporting stack layer 110. In FIG. 1, the oxide layer 124 has been patterned (such as but not limited to a photolithography process), and a plurality of first grooves R1 are formed in the oxide layer 124. Referring to the top view of the upper half of FIG. 1, a plurality of first grooves R1 are arranged in an array on a plane. More specifically, a plurality of first grooves R1 are arranged along a first direction D1, a second direction D2 and a third direction D3, respectively. The first direction D1, the second direction D2 and the third direction D3 are not parallel to each other or perpendicular to each other. Preferably, four adjacent first grooves R1 in FIG. 1 can be arranged in a diamond shape. That is to say, the distance from any first groove R1 to an adjacent first groove R1 along the second direction D2 may be equal to the distance from the first groove R1 to another adjacent first groove R1 along the third direction D3, but the present invention is not limited to this.

Here, for the convenience of explanation, a first area A1, a second area A2 and a third area A3 are defined in FIG. 1. The first groove R1 is located in the first area A1 and the second area A2, while the third area A3 does not contain the first groove R1. The second area A2 is located at the edge of the first area A1 and surrounds or surrounds the first area A1, while the third area A3 surrounds the second area A2. That is, the range near the edge of the array in which the first grooves R1 are arranged is defined as the second area A2, and the area outside the second area A2 that does not contain the first grooves R1 is defined as the third area A3. In this embodiment, the width of the second region A2 includes about 1 to 2 first grooves R1, but the present invention is not limited to this.

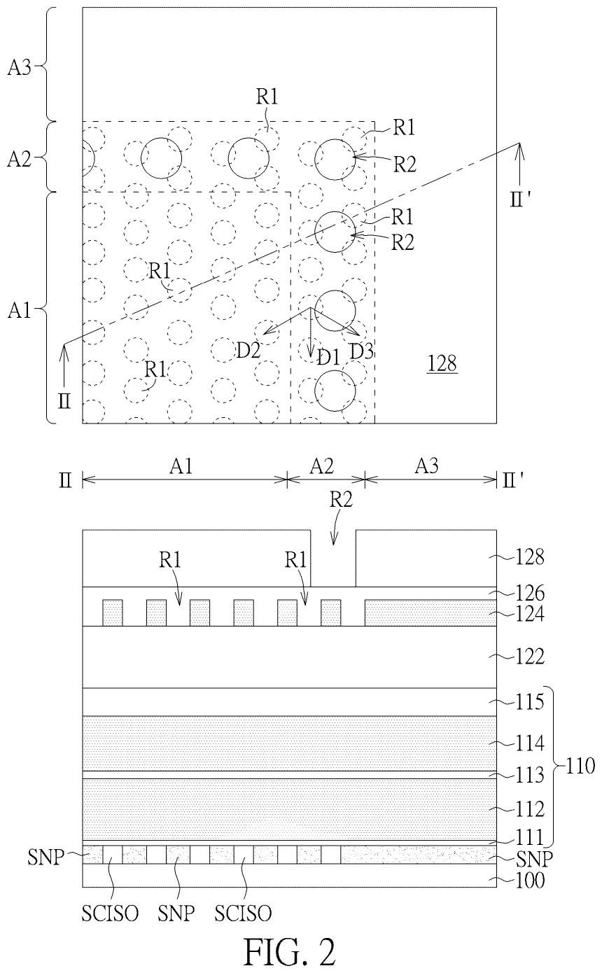

The upper half of FIG. 2 is a top view of the semiconductor device, and the lower half of FIG. 2 is a sectional view taken along section line II-II′. As shown in FIG. 2, a bottom anti-reflective coating layer 126 and a photoresist layer 128 are formed to cover the polysilicon layer 122 and the patterned oxide layer 124. Then a photolithography process is performed to pattern the photoresist layer 128, and a plurality of second grooves R2 are formed in the photoresist layer 128. Reference can be made to the top view of FIG. 2, in which the second groove R2 is located in the second area A2, and the shape of the second groove R2 can be rectangular, circular, polygonal or other shapes, and the present invention is not limited to this. Preferably, the shape of the second groove R2 in this embodiment is circular, because according to the experiment of the applicant, the structure of the circular second groove R2 is stable, which is beneficial to improving the structural strength of the capacitor structure formed subsequently. It is worth noting that from the top view of FIG. 2, each second groove R2 overlaps with a plurality of first grooves R1. More specifically, each second groove R2 is located between three adjacent first grooves R1 and overlaps with the three first grooves R1.

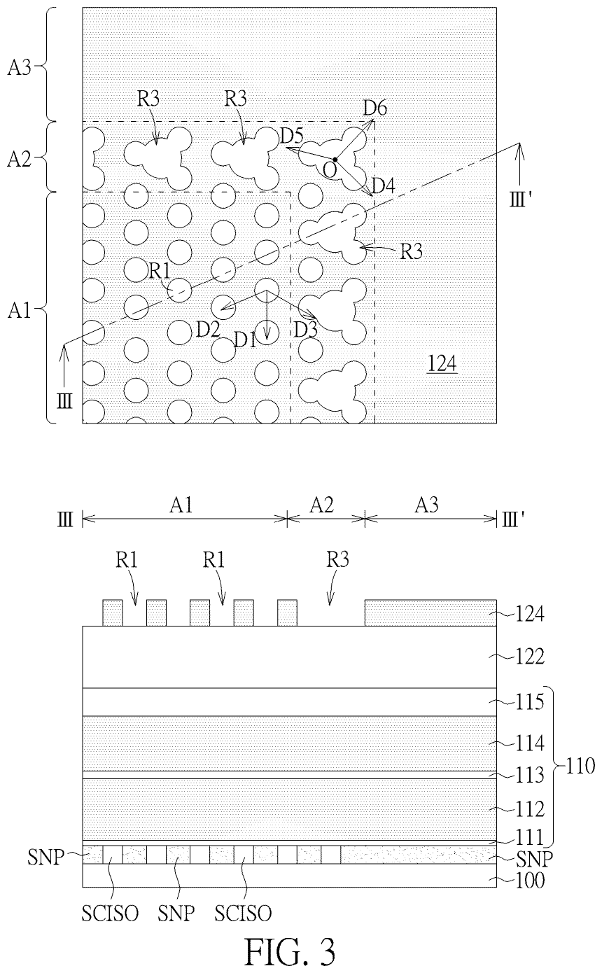

The upper half of FIG. 3 is a top view of the semiconductor device, and the lower half of FIG. 3 is a sectional view taken along section line III-III′. As shown in FIG. 3, the etching step is continued, and the pattern of the second groove R2 is transferred to the lower material layer. Specifically, the pattern of the second groove R2 is transferred into the underlying oxide layer 124, and the redundant bottom anti-reflective coating layer 126 and photoresist layer 128 are removed. As mentioned above, because part of the first groove R1 overlaps with the second groove R2, the overlapping part of the first groove R1 and the second groove R2 is defined as the third groove R3 here. That is, at this time, the oxide layer 124 contains a plurality of first grooves R1 and a plurality of third grooves R3. From the top view, each third groove R3 is located in the second area A2, that is, on the periphery of the array arranged by the first grooves R1. In addition, the third groove R3 has a special shape, in which there are three arc-shaped protruding parts extending outward from the central point O of the third groove R3 in three different directions D4, D5 and D6 respectively. The directions D4, D5 and D6 are different from the first direction D1, the second direction D2 and the third direction D3 mention above. Specifically, the directions in which the central point of the second groove R2 faces the central points of the three overlapping first grooves R1 are defined as directions D4, D5 and D6, respectively, but not limited thereto.

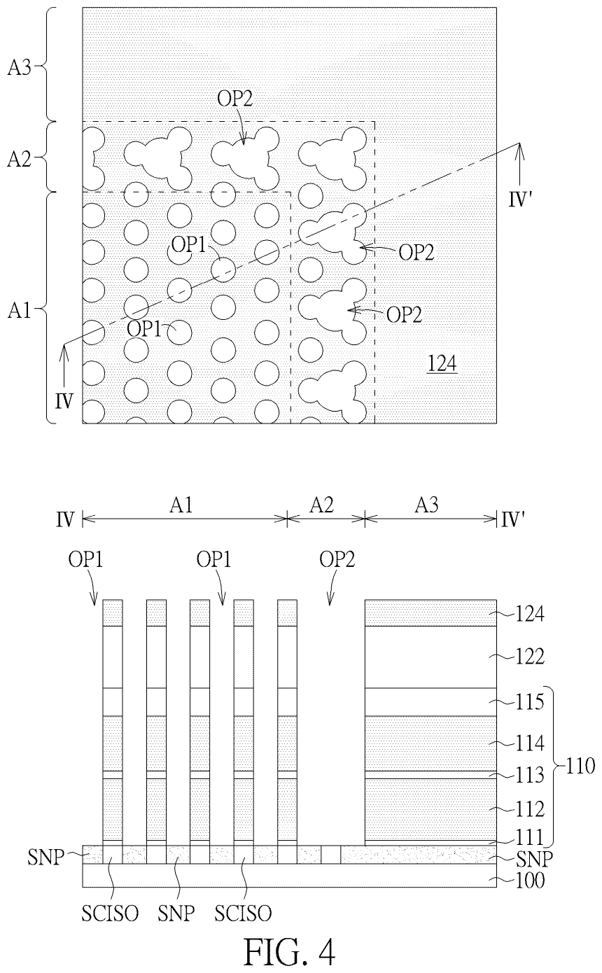

The upper half of FIG. 4 is a top view of the semiconductor device, and the lower half of FIG. 4 is a sectional view taken along section line IV-IV′. As shown in FIG. 4, a pattern transfer step, such as an etching step, is continued, and the patterns of the first groove R1 and the third groove R3 are transferred to the lower supporting stack layer 110 with the oxide layer 124 as a mask. For example, a dry etching process is used to sequentially penetrate the fifth supporting layer 115, the fourth supporting layer 114, the third supporting layer 113, the second supporting layer 112 and the first supporting layer 111 to form a plurality of first capacitor through holes OP1 and a plurality of second capacitor through holes OP2 in the supporting stack layer 110. Here, each first capacitor through hole OP1 corresponds to the position of the first groove R1, and each second capacitor through hole OP2 corresponds to the position of the third groove R3. In addition, the bottom of each first capacitor through hole OP1 exposes a lower storage node pad SNP, and the area of each second capacitor through hole OP2 is larger than the area of the first capacitor through hole OP1, so the bottom of each second capacitor through hole OP2 exposes a plurality of (more than two) storage node pads SNP below.

The positions of the first capacitor through hole OP1 and the second capacitor through hole OP2 formed here will form a plurality of capacitor structures in the following steps. The first capacitor through holes OP1 are arranged in an array, and the second capacitor through holes OP2 are located at the periphery of the array arranged by the first capacitor through holes OP1. The shape of the second capacitor through hole OP2 is the same as the third groove R3, wherein the second capacitor through hole OP2 has a larger area than the first capacitor through hole OP1, so the capacitor structure formed in the second capacitor through hole OP2 later is more stable. In this embodiment, the second capacitor through hole OP2 can protect the first capacitor through hole OP1 located near the edge.

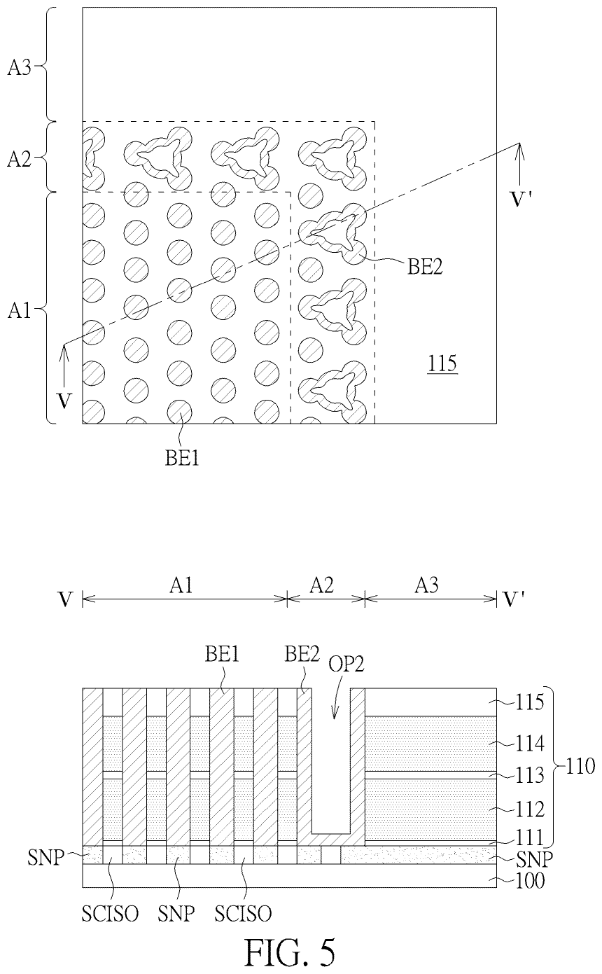

The upper half of FIG. 5 is a top view of the semiconductor device, and the lower half of FIG. 5 is a sectional view taken along section line V-V′. As shown in FIG. 5, a deposition and etching back process is performed to form a plurality of lower electrodes BE1 in the first capacitor through hole OP1 and a second lower electrode BE2 in the second capacitor through hole OP2. In an embodiment, the manufacturing process of the first lower electrode BE1 and the second lower electrode BE2 includes but is not limited to the following steps. First, electrode material layers are formed in the first capacitor through hole OP1 and the second capacitor through hole OP2, for example, metal materials with low resistance such as titanium nitride, aluminum, titanium, copper or tungsten, and preferably titanium nitride. The electrode material layer may fill up each first capacitor through hole OP1 and cover the inner surface and bottom surface of the second capacitor through hole OP2, but does not fill up the second capacitor through hole OP2. Then, the redundant electrode material layers located outside the first capacitor through hole OP1 and the second capacitor through hole OP2 are removed, and a first lower electrode BE1 with an I-shaped cross section is formed in the first capacitor through hole OP1, and a second lower electrode BE2 with a U-shaped cross section is formed in the second capacitor through hole OP2. It can be understood that the first lower electrode BE1 and the second lower electrode BE2 have the same material (both made of electrode material layers). The bottom of the second lower electrode BE2 spans at least two storage node contact pads SNP.

In addition, from the top view, as shown in the upper half of FIG. 5, since the first lower electrode BE1 fills up each first capacitor through hole OP1 and the first capacitor through hole OP1 has a circular profile, the first lower electrode BE1 also has a circular profile. In addition, because the second lower electrode BE2 does not fill up the second capacitor through hole OP2, but covers the side surface of the second capacitor through hole OP2, from the top view, a part of the recess left in the middle of the second capacitor through hole OP2 is not filled up by the second lower electrode BE2, and the second lower electrode BE2 in the second capacitor through hole OP2 is formed in a conformal manner on the inner surface of the second capacitor through hole OP2, and the outer boundary of the second lower electrode BE2 has three arc-shaped protruding part corresponding to the three top ends of the triangle (please refer to the shape shown in FIG. 5 for details).

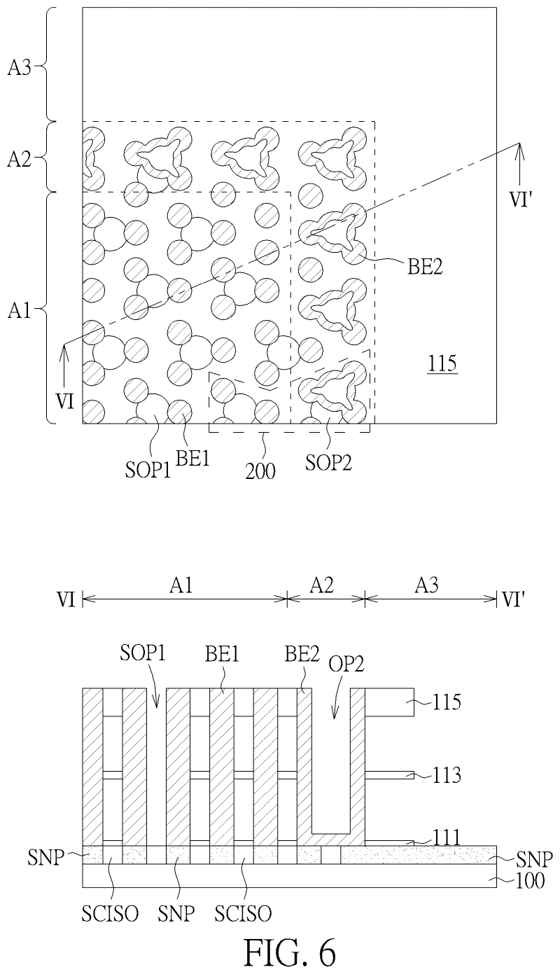

The upper half of FIG. 6 is a top view of the semiconductor device, and the lower half of FIG. 6 is a sectional view taken along section line VI-VI′. As shown in FIG. 6, a wet etching process can be performed, for example, an etchant such as tetramethylammonium hydroxide (TMAH) is introduced to remove the remaining fourth supporting layer 114 and second support material layer 112. At this time, the first support material layer 111, the third support material layer 113 and the fifth support material layer 115 left in the supporting stack layer 110 are located between the first lower electrodes BE1 and/or the second lower electrodes BE2, which can be used as a structure for stabilizing the lower electrodes.

In addition, in order to further increase the supporting effect between the first lower electrode BE1 and/or the second lower electrode BE2, the etching process may be continued after the above wet etching process, and a mask (not shown) may be used to form supporting openings in the remaining supporting material layers of the supporting stack layer 110. The supporting openings may include openings between the first lower electrode BE1 and the adjacent first lower electrode BE1, which are defined as first supporting openings SOP1, and openings between the first lower electrode BE1 and the second lower electrode BE2, which are defined as second supporting openings SOP2. In this embodiment, the shape of the first supporting opening SOP1 is different from the shape of the second supporting opening SOP2. Preferably, the area of the first supporting opening SOP1 is larger than the area of the second supporting opening SOP2. And the first supporting opening SOP1 is circular or polygonal, the outer contour of the first supporting opening SOP1 extends through a plurality of adjacent first lower electrodes BE1, and partially exposes the side walls of the adjacent first lower electrodes BE1. And the outer contour of the second supporting opening SOP2 extends through a first lower electrode BE1 and an adjacent second lower electrode BE2 and partially exposes the side walls of the first lower electrode BE1 and the second lower electrode BE2. In the following steps, the first supporting opening SOP1 and the second supporting opening SOP2 will be filled into the capacitor dielectric layer and the upper electrode layer, and they will be used as the support structure between the electrodes, so the structure can be further stabilized.

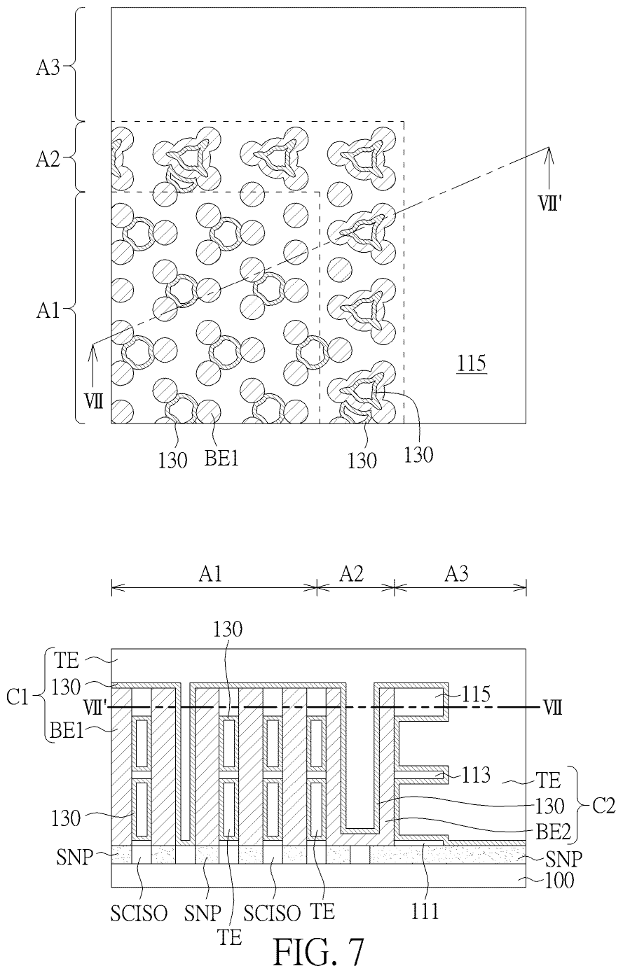

The upper half of FIG. 7 is a top view of the semiconductor device, and the lower half of FIG. 7 is a sectional view taken along section line VII-VII′. As shown in FIG. 7, at least one deposition process is performed to sequentially form the capacitor dielectric layer 130 and the upper electrode layer TE. The capacitive dielectric layer 130 is conformally covered on the exposed surfaces of the first lower electrode BE1 and the second lower electrode BE2, the fifth supporting layer 115, the first supporting opening SOP1 and the second supporting opening SOP2, while the upper electrode layer TE is covered on the capacitive dielectric layer 130, and fills up the remaining space between the second lower electrodes BE2, and the space between the first supporting openings SOP1 and the second supporting openings SOP2. Among them, part of the capacitor dielectric layer 130 and the upper electrode layer TE can be further formed in the space between the first supporting layer 111 and the third supporting layer 113, and the space between the third supporting layer 113 and the fifth supporting layer 115, so as to increase the contact area and improve the capacitance value. In one embodiment, the capacitor dielectric layer 130 includes a dielectric material with high dielectric coefficient, preferably zirconia-alumina-zirconia (ZAZ), and the upper electrode layer TE includes a low-resistance metal material such as titanium nitride, aluminum, titanium, copper or tungsten, a semiconductor material such as SiGe or a combination of the above materials, preferably including a multilayer structure of titanium nitride and SiGe, but not limited thereto. It is worth noting that the upper electrode layer TE in FIG. 7 covers all the device surfaces, but in order to see the structural features of this embodiment from the top view more clearly, the top view of FIG. 7 corresponds to the section line VII-VII′ in the section view, so the material layers such as the first lower electrode BE1, the second lower electrode BE2, the capacitor dielectric layer 130 and the upper electrode layer TE can be seen from the top view.

Up to this step, a plurality of capacitor structures have been formed, which are composed of a first lower electrode BE1 and/or a second lower electrode BE2, a capacitor dielectric layer 130 and an upper electrode layer TE stacked in sequence. More specifically, each capacitor structure composed of the first lower electrode BE1, the capacitor dielectric layer 130 and the upper electrode layer TE can be defined as the first capacitor structure C1, and each capacitor structure composed of the second lower electrode BE2, the capacitor dielectric layer 130 and the upper electrode layer TE can be defined as the second capacitor structure C2. The second capacitor structures C2 are located at the periphery of the first capacitor structures C1 array, which can protect the peripheral structure of the first capacitor structures C1 array. In other words, each second capacitor structure C2 can be regarded as a dummy capacitor structure. The first capacitor structures C1 and the capacitor structures C2 serve as storage nodes (SN) of the semiconductor device, wherein each capacitor can be electrically connected to a transistor component (not shown) in the substrate 100 through a storage node pad SNP. Under this arrangement, the semiconductor device of this embodiment can form a dynamic random access memory (DRAM) device, which is composed of at least one of the transistor elements and at least one of the first capacitor structures C1 as the smallest memory cell in a DRAM array to receive voltage information from the bit line and the buried word line (buried gate).

Before the capacitor structure is formed, the contact plug can be formed to connect the capacitor structure. Comprise forming an interlay dielectric layer to cover that sequential semiconductor structure, and then forming a contact plug made of a conductive material on the interlay dielectric layer to electrically connect the capacitor structure. The contact plug includes, for example, aluminum, titanium, tantalum, tungsten, niobium, molybdenum, copper and other materials, preferably including tungsten, but not limited thereto. The above characteristics belong to the well-known technology in the field, so the specification won't repeat them here.

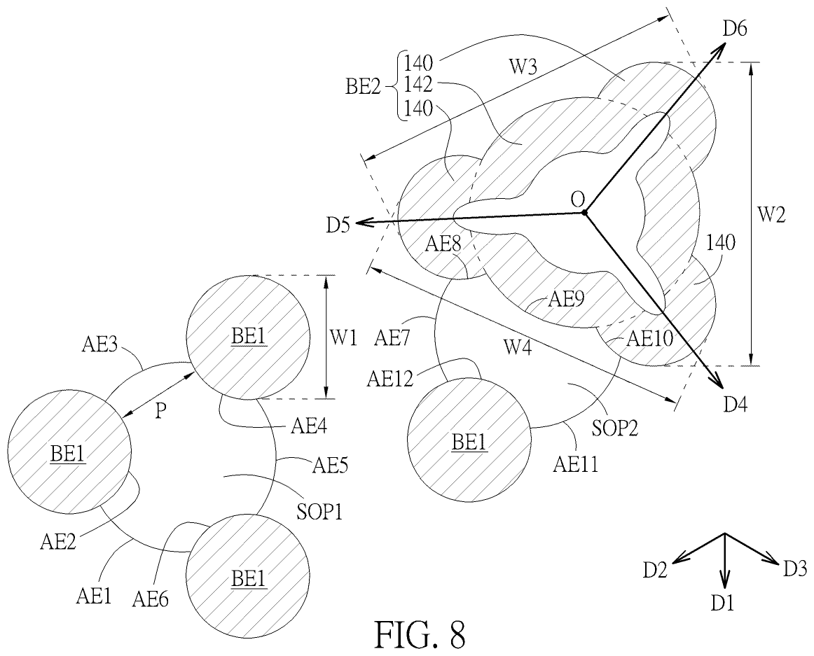

In addition, the shapes of the first supporting opening SOP1 and the second supporting opening SOP2 and the shape of the second lower electrode BE2 of the present invention also have characteristics. Reference can be made to FIG. 8, which shows a partially enlarged top view of the first supporting opening SOP1, the second supporting opening SOP2, the first lower electrode BE1 and the second lower electrode BE2 of the semiconductor device of the present invention. FIG. 8 is a partially enlarged schematic diagram of the steps shown in FIG. 6, and reference can be made to the range 200 in FIG. 6, wherein the range 200 includes the first supporting opening SOP1, the second supporting opening SOP2, the first lower electrode BE1 and the second lower electrode BE2. As shown in FIG. 8, when viewed from the top, the first supporting opening SOP1 is located between three first lower electrodes BE1, and each first lower electrode BE1 presents a circular profile, and part of the boundaries of the first supporting opening SOP1 contact the side wall of the first lower electrode BE1, while the boundaries of other first supporting openings SOP1 that do not contact the side wall of the first lower electrode BE1 can be roughly connected into a circle. That is to say, the boundary of the first supporting opening SOP1 can be composed of six arc boundaries which are connected with each other and defined as arc boundaries AE1, AE2, AE3, AE4, AE5 and AE6 respectively. Among them, arc boundaries AE1, AE3 and AE5 have the same radius of curvature, while arc boundaries AE2, AE4 and AE6 have the same radius of curvature, and the radius of curvature of arc boundary AE1 is larger than that of arc boundary AE2.

Please continue to refer to FIG. 8. From the top view, the second supporting opening SOP2 is located between the first lower electrode BE1 and the second lower electrode BE2, in which the second lower electrode BE2 may include a main body 142 located in the middle and three protruding parts 140 located beside the main body 142, wherein the main body 142 is roughly circular and the protruding parts 140 are arc-shaped, and the three protruding parts 140 extend outward from the central point O of the main body 142 along directions D4, D5 and D6 respectively.

As for the second supporting opening SOP2, it is located between the first lower electrode BE1 and the second lower electrode BE2. Wherein the shape of the second supporting opening SOP2 may be a plurality of arc-shaped shapes. Taking this embodiment as an example, the boundary of the second supporting opening SOP2 can be composed of six arc boundaries which are connected with each other and defined as arc boundaries AE7, AE8, AE9, AE10, AE11 and AE12 respectively. Among them, arc boundary AE7 and AE11 have the same radius of curvature, while arc boundaries AE8, AE10 and AE12 have the same radius of curvature. In addition, the radius of curvature of arc boundary AE7 is greater than that of arc boundary AE8, and the radius of curvature of arc boundary AE9 is greater than that of arc boundary AE7, but it is not limited to this. In addition, the radius of curvature of the arc boundary AE7 may be equal to that of the arc boundary AE1 of the first supporting opening SOP1, and the radius of curvature of the arc boundary AE8 may be equal to that of the arc boundary AE2 of the first supporting opening SOP1, but the present invention is not limited to this.

The boundary between the first supporting opening SOP1 and the second supporting opening SOP2 is composed of a plurality of arc boundaries. According to the experiment of the applicant, the shape composed of arc boundaries has a relatively stable structure. Therefore, it is beneficial to improve the supporting effect of the capacitor structure. However, the present invention is not limited to this, and the shapes of the first supporting opening SOP1 and the second supporting opening SOP2 can be adjusted as required.

In addition, as shown in FIG. 8, the first lower electrode BE1 has a first dimension (that is, the diameter of the first lower electrode BE1), the second lower electrode BE2 has a second dimension W2, a third dimension W3 and a fourth dimension W4 in the first direction D1, the second direction D2 and the third direction D3, respectively, and the shortest distance between any two first lower electrodes BE1 is defined as a first pitch P, wherein at least one of the second dimension W2, the third dimension W3 and the fourth dimension W4 is not less than the sum of twice the first dimension W1 and the first pitch P, that is, taking the second dimension W2 as an example, the condition that W2≥2W1+P is satisfied. The rest of the third dimension W3 and the fourth dimension W4 are the same.

Other features of the first lower electrode BE1, the second lower electrode BE2, the first supporting opening SOP1 and the second supporting opening SOP2 can be illustrated with reference to FIG. 8, and will not be described in detail here. It is worth noting that in other embodiments of the present invention, the size, shape and arrangement of each element can be adjusted according to actual needs, and the present invention is not limited to this.

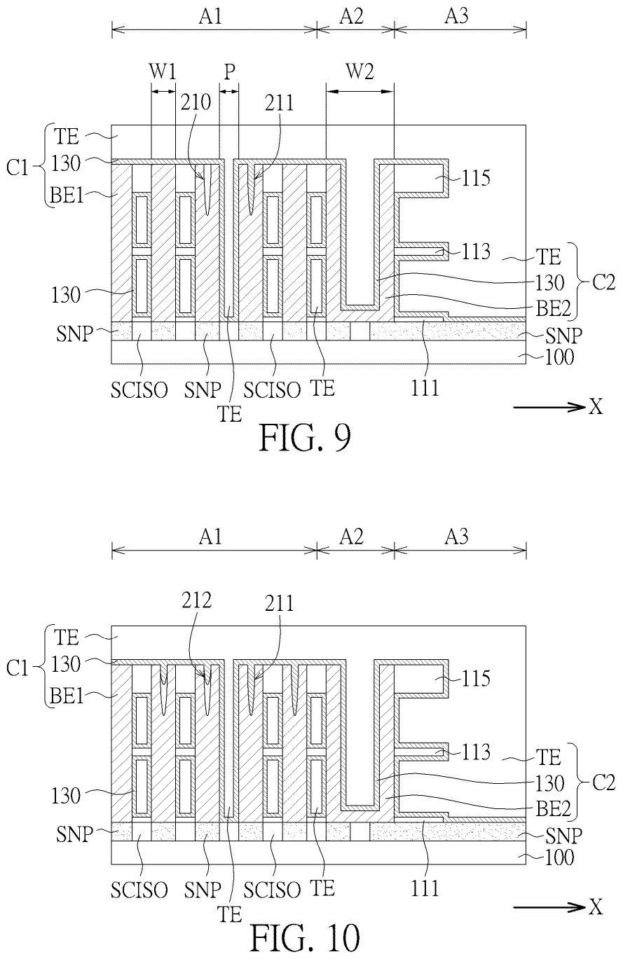

FIG. 9 and FIG. 10 are schematic cross-sectional views of semiconductor devices according to two other different embodiments of the present invention respectively. FIG. 9 and FIG. 10 can be compared with the semiconductor device of the first embodiment shown in FIG. 7 to highlight the differences between the embodiments. In order to simplify the description, the following description mainly focuses on the differences of each embodiment, and will not repeat the similarities. In addition, the same elements in various embodiments of the present invention are labeled with the same reference numerals, so as to facilitate the comparison among various embodiments. As shown in FIGS. 9 and 10, when forming the first lower electrode BE1, the process parameters can be adjusted so that the first lower electrode BE1 does not fill up the first capacitor through hole OP1, thus leaving a recess 210 in the first lower electrode BE1. Where the recess 210 may be a void, the capacitor dielectric layer 130 may fill up the recess 210 to form a fully filled structure 211 (as shown in FIG. 9), or the capacitor dielectric layer 130 may only partially fill the recess 210 to form a partially filled structure 212 (as shown in FIG. 10), or the capacitor dielectric layer 130 is not filled in the recess 210, but covers the recess 210, so that the recess 210 is reserved to form an air void (as shown in FIG. 9). It can be understood that with the adjustment of the process parameters, the first lower electrodes BE1 with different shapes can also be combined with each other, for example, the structures of FIG. 9 and FIG. 10 can be combined with each other. All the above variations are within the scope of the present invention.

Based on the above description and drawings, please refer to the top views of FIGS. 1-8. The present invention provides a semiconductor device, including a substrate 100, on which a plurality of first lower electrodes BE1 are arranged in an array in a first direction D1, a second direction D2 and a third direction D3 which are not perpendicular to each other, the outer contour of each first lower electrode BE1 is circular, and a plurality of second lower electrodes BE2 are located on the substrate 100. The outer contour of the second lower electrode BE2 includes a main body 142 and three protruding parts 140, wherein the main body 142 is circular and the three protruding parts 142 are arc-shaped, and extend outward from the center O of the main body 142 along the fourth direction D4, the fifth direction D5 and the sixth direction D6, respectively.

In some embodiments of the present invention, a plurality of second lower electrodes BE2 surround the array arranged by the first lower electrodes BE1.

In some embodiments of the present invention, the capacitor dielectric layer 130 is further included, which is located on the first lower electrode BE1 and the second lower electrode BE2, and the upper electrode layer TE is located on the capacitor dielectric layer 130.

In some embodiments of the present invention, an opening (i.e., a second capacitor through hole OP2) is located in each second lower electrode BE2, and the capacitor dielectric layer 130 or/and the upper electrode layer TE are filled in the opening OP2.

In some embodiments of the present invention, a recess 210 is located in the at least one lower electrode BE1, and the recess 210 may include a void 210, a void partially filled with a capacitor dielectric layer (i.e., the partially filled structure 212) or a fully filled capacitor dielectric layer (i.e., the fully filled structure 211).

In some embodiments of the present invention, the first lower electrode BE1 has a first dimension W1, and the second lower electrode BE2 has a second dimension W2, a third dimension W3 and a fourth dimension W4 in the first direction D1, the second direction D2 and the third direction D3, respectively. The shortest distance between any two first lower electrodes BE1 is defined as a first pitch P, wherein at least one of the second dimension W2, the third dimension W3 and the fourth dimension W4 is not less than the sum of twice the first dimension W1 and the first pitch P.

In some embodiments of the present invention, it further includes a supporting layer (the supporting stack layer 110) surrounding the first lower electrode BE1 and the second lower electrode BE2. The supporting layer 110 includes a first supporting opening SOP1 between a plurality of first lower electrodes BE1 and a second supporting opening SOP2 between the first lower electrode BE1 and the second lower electrode BE2.

In some embodiments of the present invention, the area of the second supporting opening SOP2 is smaller than the area of the first supporting opening SOP1.

In some embodiments of the present invention, the shape of the second supporting opening SOP2 is different from the shape of the first supporting opening SOP1.

In some embodiments of the present invention, the first supporting opening SOP1 is circular or polygonal, and the outer contour of the first supporting opening SOP1 extends through a plurality of adjacent first lower electrodes BE1, and partially exposes the side walls of the adjacent first lower electrodes BE1.

In some embodiments of the present invention, the second supporting opening SOP2 is circular or polygonal, and the outer contour of the second supporting opening SOP2 extends through at least one first lower electrode BE1 and an adjacent second lower electrode BE2, and partially exposes the side walls of the first and second lower electrodes BE1 and BE2.

In some embodiments of the present invention, the second supporting opening SOP2 partially exposes the side wall of the main body 142 of the second lower electrode BE2 and the side wall of at least one protruding part 140.

In some embodiments of the present invention, the outer contour of the second lower electrode BE2 is alternately composed of three first arcs with a first radius of curvature and three second arcs with a second radius of curvature, wherein the first radius of curvature is smaller than the second radius of curvature.

Referring to the cross-sectional views of FIGS. 1-10, the present invention further provides a semiconductor device, which comprises a substrate 100, wherein a plurality of first lower electrodes BE1 and second lower electrodes BE2 are located on the substrate 100, and the plurality of first lower electrodes BE1 are arranged adjacent to each other in an array, wherein, as viewed from the cross-section, each first lower electrode BE1 presents an I-shaped profile, and each second lower electrode BE2 presents a U-shaped profile.

In some embodiments of the present invention, when viewed from the cross-section, the second lower electrode BE2 is located at one side of the array in which the first lower electrodes BE1are arranged.

In some embodiments of the present invention, the capacitor dielectric layer 130 is further included, which is located on the first lower electrode BE1 and the second lower electrode BE2, and the upper electrode layer TE is located on the capacitor dielectric layer 130.

In some embodiments of the present invention, as viewed from the cross section, the second lower electrode BE2 surrounds and forms an opening OP2, and the opening OP2 is filled with the capacitor dielectric layer 130 and/or the upper electrode layer TE.

In some embodiments of the present invention, the cross-sectional view further includes a recess 210 located in at least one first lower electrode BE1, and the recess 210 may include a void 210, a void partially filled with a capacitor dielectric layer (i.e., the partially filled structure 212) or a fully filled capacitor dielectric layer (i.e., the fully filled structure 211).

In some embodiments of the present invention, the first lower electrode BE1 has a first dimension W1 and the second lower electrode BE2 has a second dimension W2 in a first direction parallel to the substrate (the X direction in FIG. 9), and the shortest distance between any two first lower electrodes BE1 in the first direction is defined as a first pitch P, where the second dimension W2 is not less than the sum of twice the first dimension W1 and the first pitch P.

In some embodiments of the present invention, a plurality of contact pad SNPs are located on the substrate 100, and the contact pad SNPs are located between the second lower electrode BE2 and the substrate 100, wherein the second lower electrode BE2 contacts the plurality of contact pad SNPs (the second lower electrode BE2 spans at least two contact pad SNPs).

According to FIGS. 1 to 7, the present invention provides a manufacturing method of a semiconductor device, which is characterized by comprising providing a substrate 100, forming a supporting stack layer 110 on the substrate 100, forming a mask layer (including a polysilicon layer 122, an oxide layer 124, a bottom anti-reflective coating layer 126 and a photoresist layer 128) on the supporting stack layer 110, and performing a first patterning step (shown in FIG. 1) to form a plurality of first layers in the mask layer. A second patterning step (as shown in FIG. 2) is performed to form a plurality of second grooves R2 in the mask layer, wherein each second groove R2 overlaps with a plurality of first grooves R1 in the top view, and the overlapping part of each first groove R1 and each second groove R2 is defined as a plurality of third grooves R3, and an etching step is performed to form a plurality of first capacitor through holes OP1 and a plurality of second capacitor through holes OP2 in the supporting stacked layer 110 by using the patterned mask layer as a mask.

In some embodiments of the present invention, it is characterized in that each first capacitor through hole OP1 corresponds to each first groove R1, and each second capacitor through hole OP2 corresponds to each third groove R3.

In some embodiments of the present invention, it is characterized by further filling the lower electrode layer into each of the first capacitor through holes OP1 and the second capacitor through holes OP2 to form a first lower electrode BE1 and a second lower electrode BE2.

In some embodiments of the present invention, it is characterized in that, when viewed from the top, each first capacitor through hole OP1 is circular, and each second capacitor through hole OP2 includes a main body 142 and three protruding parts 140, wherein the main body 142 is circular and the three protruding parts 140 are arc-shaped, which are respectively distributed in the fourth direction D4, the fifth direction D5 and the sixth direction D6 which are not perpendicular to each other.

In some embodiments of the present invention, it is characterized in that the area of the second capacitor through hole OP2 is larger than three times of the area of the first capacitor through hole OP1.

In some embodiments of the present invention, the formation of the first lower electrode BE1 and the second lower electrode BE2 further includes forming the supporting openings in the supporting stacked layer 110, the supporting openings include a first supporting opening SOP1 between a plurality of first lower electrodes BE1 and a second supporting opening SOP2 between a first lower electrode BE1 and a second lower electrode BE2, wherein the area of the first supporting opening SOP1 is larger than the area of the second supporting opening SOP2.

In some embodiments of the present invention, it is characterized by further forming a plurality of contact pad SNPs on the substrate 100, wherein each first capacitor through hole OP1 corresponds to one contact pad SNP, and the second capacitor through hole OP2 corresponds to a plurality of contact pad SNPs.

The present invention is characterized in that, when viewed from the top, the second capacitor through hole OP2 is located in the second area A2, and the second lower electrode BE2 in the second capacitor through hole OP2 surrounds the periphery of the first lower electrodes BE1 of the plurality of first capacitor through holes OP1, and the shape of the second lower electrode BE2 is different from that of the first lower electrode BE1. In the manufacturing process, the second area A2 is adjacent to the blank area (that is, the third area A3) where elements are not formed, so there is a big difference in element density between the two areas, which is easily affected by the loading effect and leads to the damage of the capacitor structure in the second area A2. In the second area A2, the second capacitor through hole OP2 with a larger area and a special shape is manufactured by overlapping the first groove R1 and the second groove R2, so that the second capacitor through hole OP2 has a larger coverage area compared with a plurality of first capacitor through holes OP1 located in the first area A1, and the second capacitor through hole OP2 is composed of three first capacitor through holes OP1 and a central through hole, and has a stable structure and is less likely to be damaged due to loading effect. Therefore, the invention is helpful to improve the quality of the capacitor structure located in the edge region.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a plurality of first lower electrodes are positioned on the substrate, the first lower electrodes are arranged in an array along a first direction, a second direction and a third direction, wherein the first direction, the second direction and the third direction are not perpendicular to each other, and the outer contour of each first lower electrode is circular; and
a plurality of second lower electrodes positioned on the substrate, and the outer contour of each second lower electrode includes a main body and three protruding parts, wherein the main body is circular, and the three protruding parts are arc-shaped and extend outward from the center of the main body along a fourth direction, a fifth direction and a sixth direction respectively.

2. The semiconductor device according to claim 1, wherein the plurality of second lower electrodes surround the array arranged by the first lower electrodes.

3. The semiconductor device according to claim 1, further comprising:
a capacitive dielectric layer located on the first lower electrode and the second lower electrode;
an upper electrode layer located on the capacitor dielectric layer.

4. The semiconductor device according to claim 3, further comprising an opening located in each of the second lower electrodes, and the capacitor dielectric layer or/and the upper electrode layer is filled in the opening.

5. The semiconductor device according to claim 3, further comprising a recess located in at least one of the first lower electrodes, wherein the recess comprises a void, a void partially filled by the capacitor dielectric layer, or void fully filled by the capacitor dielectric layer.

6. The semiconductor device according to claim 1, wherein the first lower electrode has a first dimension, and the second lower electrode has a second dimension, a third dimension and a fourth dimension in the first direction, the second direction and the third direction, respectively, and the shortest distance between any two of the first lower electrodes is defined as a first pitch, wherein at least one of the second dimension, the third dimension and the fourth dimension is not less than twice the sum of the first dimension and the first pitch.

7. The semiconductor device according to claim 1, further comprising:
a supporting layer surrounding the first lower electrode and the second lower electrode, the supporting layer comprising a first supporting opening between the plurality of first lower electrodes, and a second supporting opening between the first lower electrode and the second lower electrode.

8. The semiconductor device according to claim 7, wherein an area of the second supporting opening is smaller than an area of the first supporting opening.

9. The semiconductor device according to claim 7, wherein the shape of the second supporting opening is different from the shape of the first supporting opening.

10. The semiconductor device according to claim 7, wherein the first supporting opening is circular or polygonal, and the outer contour of the first supporting opening extends through a plurality of adjacent first lower electrodes, and partially exposes the side walls of the adjacent first lower electrodes.

11. The semiconductor device according to claim 7, wherein the second supporting opening is circular or polygonal, and the outer contour of the second supporting opening extends through at least one of the first lower electrodes and an adjacent second lower electrode, and partially exposes side walls of the first lower electrode and the second lower electrode.

12. The semiconductor device according to claim 11, wherein the second supporting opening portion exposes a side wall of the main body of the second lower electrode and a side wall of at least one of the protruding parts.

13. The semiconductor device according to claim 1, wherein the outer contour of the second lower electrode is alternately composed of three first arcs with a first radius of curvature and three second arcs with a second radius of curvature, wherein the first radius of curvature is smaller than the second radius of curvature.

14. A semiconductor device comprising:
a substrate;
a plurality of first lower electrodes and second lower electrodes located on the substrate, and the first lower electrodes are arranged adjacent to each other in an array, wherein, when viewed from a cross section, each first lower electrode presents an I-shaped profile and each second lower electrode presents a U-shaped profile.

15. The semiconductor device according to claim 14, wherein when viewed from the cross section, the second lower electrode is located at one side of the array in which the first lower electrodes are arranged.

16. The semiconductor device according to claim 14, further comprising:
a capacitive dielectric layer located on the first lower electrode and the second lower electrode;
an upper electrode layer located on the capacitor dielectric layer.

17. The semiconductor device according to claim 16, wherein an opening is formed around the second lower electrode when viewed from a cross section, and the opening is filled with the capacitor dielectric layer or/and the upper electrode layer.

18. The semiconductor device according to claim 16, further comprising a recess in at least one of the first lower electrodes when viewed from the cross section, wherein the recess include a void, a void partially filled by the capacitor dielectric layer, or void fully filled by the capacitor dielectric layer.

19. The semiconductor device according to claim 14, wherein the first lower electrode has a first dimension in a first direction parallel to the substrate, the second lower electrode has a second dimension in the first direction, and the shortest distance between any two first lower electrodes in the first direction is defined as a first pitch, wherein the second dimension is not less than the sum of twice the first dimension and the first pitch.

20. The semiconductor device of claim 14, further comprising a plurality of contact pads located on the substrate, the contact pads being located between the second lower electrode and the substrate, wherein the second lower electrode contacts the plurality of contact pads.
